(19) United States
(12) Patent Application Publication
(10) Pub. No.: US 2025/0072190 A1
(43) Pub. Date: Feb. 27, 2025

(54) ELECTRONIC DEVICE

(71) Applicant: InnoLux Corporation, Miao-Li County (TW)

(72) Inventors: Chia-Chun LIU, Miao-Li County (TW); Hao-Jung HUANG, Miao-Li County (TW); Kuo-Feng HSU, Miao-Li County (TW)

(21) Appl. No.: 18/783,925

(22) Filed: Jul. 25, 2024

Related U.S. Application Data
(60) Provisional application No. 63/520,955, filed on Aug. 22, 2023.

(30) Foreign Application Priority Data
May 28, 2024 (CN) 202410667824.8

(51) Int. Cl. H01L 33/62; H01L 25/075

(52) U.S. Cl. CPC H01L 33/62; H01L 25/0753

(57) ABSTRACT

An electronic device is provided. The electronic device includes at least one electrical connection structure. The at least one electrical connection structure includes a first substrate, a first conductive pad, a second substrate, a second conductive pad, a through hole, and a conductive material. The first conductive pad is disposed on the first substrate. The first conductive pad includes at least two sub-parts, and the at least two sub-parts respectively include a first upper surface. The second conductive pad is disposed on the second substrate. The second conductive pad includes a second upper surface. The through hole passes through the first substrate and exposes a portion of the second upper surface. Furthermore, the conductive material is partially disposed in the through hole and in contact with at least one first upper surface and the second upper surface.

### CROSS REFERENCE TO RELATED APPLICATIONS

This application claims the benefit of China Application No. 202410667824.8, filed May 28, 2024, which claims the benefit of provisional Application No. 63/520,955, filed Aug. 22, 2023, the entirety of which are incorporated by reference herein.

### BACKGROUND

### Technical Field

The present disclosure is related to an electronic device, and in particular it is related to an electrical connection structure of an electronic device.

### Description of the Related Art

Electronic devices such as tablet computers, notebook computers, smartphones, monitors, and televisions have become indispensable necessities in modem society. As the application of electronic devices and the habits or needs of users change, the requirements for the structure and quality of electronic devices are getting higher and higher, thereby causing electronic devices to face many different problems.

For example, in response to higher resolution or display quality requirements, the size of the electrical connection structure in the electronic device needs to be miniaturized accordingly, causing the reliability or conduction capability of the electrical connection structure to be affected.

As described above, existing electronic devices still do not meet the requirements in all respects. Further improving the performance of the electrical connection structure of electronic devices is still one of the current research topics in the industry.

### SUMMARY

In accordance with some embodiments of the present disclosure, an electronic device is provided. The electronic device includes at least one electrical connection structure. The at least one electrical connection structure includes a first substrate, a first conductive pad, a second substrate, a second conductive pad, a through hole and a conductive material. The first conductive pad is disposed on the first substrate. The first conductive pad includes at least two sub-parts, and the at least two sub-parts respectively include a first upper surface. The second conductive pad is disposed on the second substrate. The second conductive pad includes a second upper surface. The through hole passes through the first substrate and exposes a portion of the second upper surface. Furthermore, the conductive material is partially disposed in the through hole and in contact with at least one first upper surface and the second upper surface.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a top-view diagram of an electronic device in accordance with some embodiments of the present disclosure;

FIG. 2 is a cross-sectional diagram of the electronic device taken along the section line A-A′ in FIG. 1 in accordance with some embodiments of the present disclosure;

FIG. 3 is a cross-sectional diagram of an electrical connection structure of an electronic device in accordance with some embodiments of the present disclosure;

FIG. 4 is a top-view diagram of some components of an electrical connection structure of an electronic device in accordance with some embodiments of the present disclosure;

FIGS. 5A to 5E are top-view diagrams of some components of an electrical connection structure of an electronic device in accordance with some embodiments of the present disclosure;

FIGS. 6A to 6C are top-view diagrams of some components of an electrical connection structure of an electronic device in accordance with some embodiments of the present disclosure;

FIG. 7 is a cross-sectional diagram of an electrical connection structure of an electronic device in accordance with some embodiments of the present disclosure;

FIGS. 8A to 8C are top-view diagrams of some components of an electrical connection structure of an electronic device in accordance with some embodiments of the present disclosure;

FIG. 9 is a cross-sectional diagram of an electronic device in accordance with some embodiments of the present disclosure.

### DETAILED DESCRIPTION

The electronic device according to the present disclosure is described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean+/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

In accordance with the embodiments of the present disclosure, a scanning electron microscope (SEM), an optical microscope (OM), a film thickness profiler (α-step), an ellipsometer or another suitable method may be used to measure the width, thickness, height, volume or area of each element, or spacing or distance between elements. Specifically, in accordance with some embodiments, a scanning electron microscope can be used to obtain a cross-sectional image including the elements to be measured, and measure the width, thickness, height, volume or area of each element, or spacing or distance between elements.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In response to higher resolution or display quality requirements, the size of the electrical connection structure in electronic devices needs to be miniaturized accordingly, and the reliability and conduction performance of the electrical connection structure are thus challenged.

In accordance with some embodiment of the present disclosure, an electronic device including an electrical connection structure is provided. The conductive pads of the electrical connection structure have a plurality of sub-parts, which can serve as a plurality of terminals for the conductive pads to be electrically connected laterally. In this way, the contact points between the conductive material and the conductive pad can be increased, the difficulty of wiring process of the electrical connection structure can be reduced. This also allows the conductive material filling process and/or drilling process to have a larger error tolerance, thus improving the process yield. In addition, through the configuration of the aforementioned conductive pads, the total area of the conductive pads can be relatively reduced, and the volume of the through hole and/or the conductive material can be maintained or increased, which can make the electrical connection structure have improved reliability and beneficial to realize the miniaturization of the electrical connection structure. Moreover, in accordance with some embodiments of the present disclosure, the design of the electrical connection structure allows electronic components (such as driving components, etc.) to be disposed on the back side of the substrate, which can reduce the usage rate of the peripheral area of the electronic device, thereby achieving technical requirements such as borderless, narrow border or seamless tiling.

In accordance with some embodiments of the present disclosure, the electronic device may include a display device, a tiled device, a touch electronic device, a sensing device, an antenna device, a packaging device, a curved electronic device or a non-rectangular electronic device, but it is not limited thereto. The electronic device may include, for example, liquid crystal, light-emitting diode, fluorescence, phosphor, other suitable display media, or a combination thereof, but it is not limited thereto. The display device may be a non-self-luminous display device or a self-luminous display device. The electronic device may include electronic components, which may be passive components or active components, such as capacitors, resistors, inductors, diodes, driving components, transistors, etc. The diode may include a light-emitting diode (LED) or a photodiode. The light-emitting diode may include, for example, an organic light-emitting diode (OLED), a mini light-emitting diode (mini LED), a micro light-emitting diode (micro LED) or a quantum dot light-emitting diode (quantum dot LED), but it is not limited thereto. The tiled device may be, for example, a tiled display device, but it is not limited thereto. The antenna device may be, for example, a liquid-crystal antenna or a varactor diode antenna device, but it is not limited thereto. The packaging device may be used in wafer level packaging (WLP) technology or panel level packaging (WLP) technology, such as chip first or RDL first process. It should be noted that the electronic device can be any combination of the above, but it is not limited thereto. In addition, the electronic device may be a bendable or flexible electronic device. Moreover, the shape of the electronic device may be a rectangular shape, a circular shape, a polygonal shape, a shape with curved edges, or other suitable shapes. The electronic device may have a peripheral system such as a driving system, a control system, a light source system, a shelf system, etc. to support a display device or tiled device.

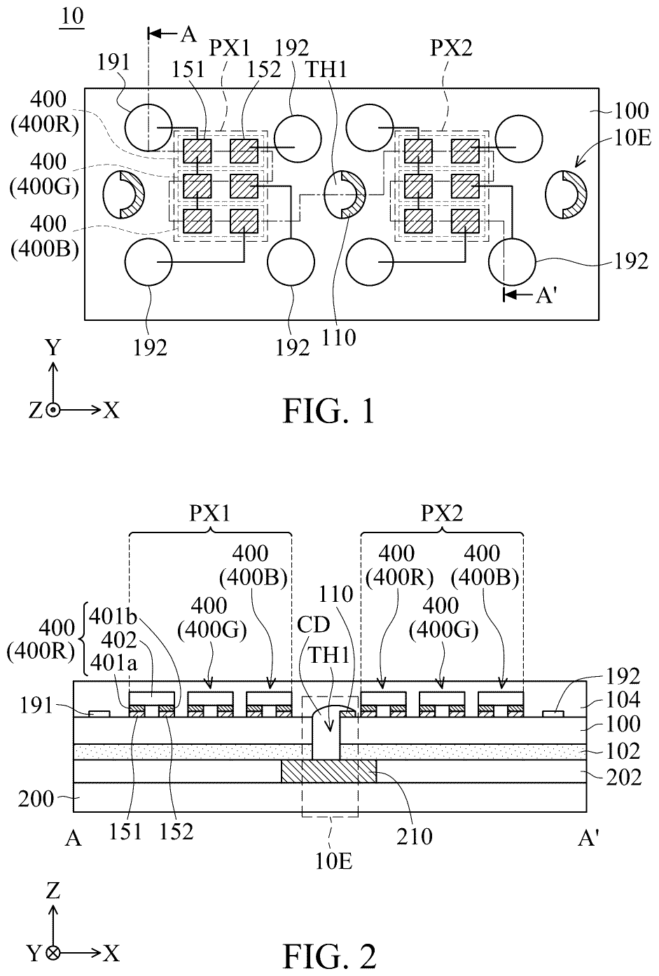

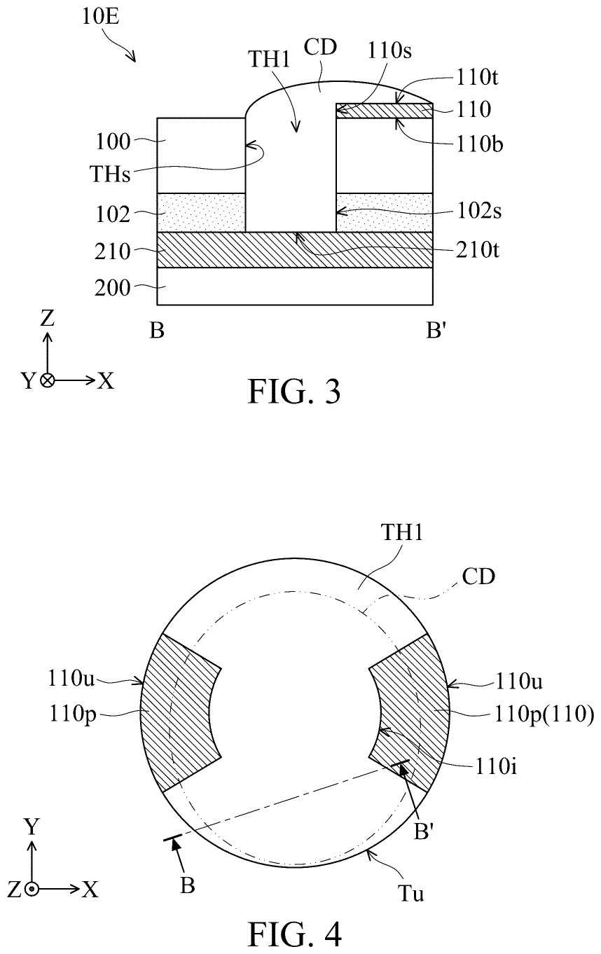

Please refer to FIG. 1 and FIG. 2. FIG. 1 is a top-view diagram of an electronic device 10 in accordance with some embodiments of the present disclosure. FIG. 2 is a cross-sectional diagram of the electronic device 10 taken along the section line A-A′ in FIG. 1 in accordance with some embodiments of the present disclosure. It should be understood that, for clarity of explanation, some components of the electronic device 10 may be omitted in the drawings, and only some components are schematically illustrated. In accordance with some embodiments, additional features may be added to the electronic device 10 described below. In accordance with some other embodiments, some features of the electronic device 10 described below may be replaced or omitted.

The electronic device 10 includes at least one electrical connection structure 10E. In the following description, the electronic device 10 is used as a display device and the electrical connection structure 10E is applied to the display device as an example, but the present disclosure is not limited thereto. It should be understood that the electrical connection structure 10E can also be applied to another suitable electronic device to provide electrical connection functions.

As shown in FIG. 1 and FIG. 2, in accordance with some embodiments, the electronic device 10 includes a first substrate 100, a second substrate 200, an electronic component 400, and an electrical connection structure 10E. The second substrate 200 may be disposed opposite to the first substrate 100. The electronic component 400 may be disposed on the first substrate 100, and the electronic component 400 may be electrically connected to another electronic component (not illustrated, such as a driving component, etc.) on the second substrate 200 through the electrical connection structure 10E. In accordance with some embodiments, the electronic component 400 includes a light-emitting diode, and the electronic device 10 can be, for example, a light-emitting diode display device. In this way, the electronic component 400 can be driven by another electronic component (not illustrated, which can be a driving component, etc.) disposed on the back side of the first substrate, which can reduce the usage rate of the usage rate of the peripheral area of the electronic device 10, thereby achieving technical requirements such as borderless, narrow border or seamless tiling. The electronic device 10 can therefore have good display quality.

In accordance with some embodiments, the first substrate 100 can be used as an active array substrate, and includes, for example, a base (not illustrated) and a circuit element layer (not illustrated) disposed on the base. The base of the first substrate 100 may include a rigid substrate, a flexible substrate, or a combination thereof. In accordance with some embodiments, the material of the base of the first substrate 100 may include glass, quartz, sapphire, polyimide (PI), polycarbonate (PC), polyethylene terephthalate (PET), polypropylene (PP), polydimethylsiloxane (PDMS), another suitable base material or a combination thereof, but it is not limited thereto. Furthermore, the circuit element layer may include, for example, a stack of at least one or more circuit elements (e.g., thin-film transistors), buffer layers, and insulating layers, but it is not limited thereto. In accordance with some embodiments, the circuit element layer is, for example, an active array layer composed of a plurality of thin-film transistors, but it is not limited thereto.

Please continue to refer to FIG. 1 and FIG. 2. In accordance with some embodiments, one or more electronic components 400 may form a pixel, and multiple pixels (for example, a pixel PX1 and a pixel PX2) may be disposed on the first substrate 100. As described above, the electronic component 400 may be a light-emitting diode. In other words, in accordance with some embodiments, each pixel may include multiple light-emitting diodes (for convenience of explanation, they are labeled as an electronic component 400R, an electronic component 400G and an electronic component 400B in FIG. 1), and the amount of light-emitting diodes is not limited. For example, the two pixels PX1 and PX2 shown in FIG. 1 may be arranged in an array by the X direction and Y direction directions in the figure (the X direction is perpendicular to the Y direction and Z direction, and the Y direction is perpendicular to the X direction and Z direction), but it is not limited thereto. It should be understood that the amount of pixels and the arrangement pattern shown in FIG. 1 are only examples. In fact, the amount of pixels may be tens, tens of thousands, or millions or more, but it is not limited thereto.

In accordance with some embodiments, the plurality of light-emitting diodes may include red light-emitting diodes, green light-emitting diodes, blue light-emitting diodes, white light-emitting diodes, yellow light-emitting diodes or light-emitting diodes of other colors, which can be adjusted according to design requirements. In accordance with some embodiments, the aforementioned electronic component 400R, electronic component 400G and electronic component 400B can serve as sub-pixels, and a combination of multiple pixels PX1 and pixels PX2 can be used to generate image patterns. In accordance with some embodiments, the amount of the light-emitting diodes in the pixel PX1 and the pixel PX2 may be three or more, and the colors of the light-emitting diodes may include red light, blue light, green light, white light, yellow light, light or another suitable color, but it is not limited thereto.

In accordance with some embodiments, the electronic component 400 may include an electrode 401a, an electrode 401b, and a body portion 402. The body portion 402 may include, for example, a first-type semiconductor layer (such as an N-type doped semiconductor layer), a second-type semiconductor layer (such as a P-type doped semiconductor layer), and a light-emitting layer located between the first-type semiconductor layer and the second-type semiconductor layer. That is, the body portion 402 may be a p-n junction light-emitting diode, but it is not limited thereto. Furthermore, although the electronic component 400 illustrated in the figure is a flip-chip LED, the present disclosure is not limited thereto. In accordance with some other embodiments, the electronic component 400 may also include a vertical LED, a face-up LED, or LED packaged by another suitable manner.

In accordance with some embodiments, the electronic component 400 may be electrically connected to the circuit element layer of the first substrate 100. Specifically, a plurality of first pads 151 and a plurality of second pads 152 may be disposed on the first substrate 100 or the circuit element layer. One of the plurality of light-emitting diodes may be disposed corresponding to the first contact pad 151 and the adjacent second contact pad 152. For example, the electrode 401a of the electronic component 400R may be electrically connected to the first contact pad 151, and the electrode 401b may be electrically connected to the second contact pad 152, but it is not limited thereto. In this way, the first contact pad 151 and the second contact pad 152 can respectively serve as pads connected to the positive electrode or the negative electrode of the electronic component 400. For example, the electronic component 400 may be electrically connected to the first contact pad 151 and the second contact pad 152 through wire bonding, flip chip die bonding, or eutectic die bonding. In addition, in accordance with some other embodiments, the electronic component 400 may also use a transfer layer including conductive lines and insulating layers, so that the electrode 401a and/or the electrode 401b can be electrically connected to the circuit elements (for example, thin-film transistors) or circuit layers in the circuit element layer through the conductive lines, but it is not limited thereto.

In accordance with some embodiments, the electronic device 10 may optionally include a first test pad 191 and a plurality of second test pads 192. The first test pad 191 and the second test pads 192 may be respectively disposed adjacent to one side of the pixel (for example, the pixel PX1), but it is not limited thereto. The first test pad 191 and the second test pads 192 may be electrically connected to the circuit element layer of the first substrate 100, but it is not limited thereto. The first test pad 191 may connect multiple first pads 151 in series. The second test pads 192 may be electrically connected to the second pads 152 respectively. In accordance with some embodiments, the first test pad 191 and the second test pads 192 can serve as test electrodes for detecting the electrical quality of the plurality of electronic components 400 in the pixel PX1 and the pixel PX2.

The materials of the first test pad 191, the second test pad 192, the first contact pad 151 and the second contact pad 152 may include conductive materials. In accordance with some embodiments, the first test pad 191, the second test pad 192, the first contact pad 151 and the second contact pad 152 may include a metal conductive material, such as molybdenum (Mo), titanium (Ti), Tantalum (Ta), niobium (Nb), hafnium (Hf), nickel (Ni), chromium (Cr), cobalt (Co), zirconium (Zr), Tungsten (W), aluminum (Al), copper (Cu), silver (Ag), gold (Au), alloys of the above materials, another suitable conductive material or a combination thereof, but it is not limited thereto. In accordance with some embodiments, the first test pad 191, the second test pad 192, the first contact pad 151 and the second contact pad 152 may include a transparent conductive material. The transparent conductive material may include, for example, a transparent conductive oxide (TCO), such as indium tin oxide (ITO), antimony zinc oxide (AZO), tin oxide (SnO), zinc oxide (ZnO), indium zinc oxide (indium zinc oxide, IZO), indium gallium zinc oxide (IGZO), indium tin zinc oxide (ITZO), antimony tin oxide (ATO), another suitable transparent conductive material, or a combination thereof, but it is not limited thereto.

As shown in FIG. 2, in accordance with some embodiments, the electronic device 10 may further include a cover layer 104 disposed on the first substrate 100. Furthermore, in accordance with some embodiments, the cover layer 104 may be disposed on the circuit element layer of the first substrate 100, the cover layer 104 may cover the first test pad 191 and the second test pad 192, and may at least partially cover electronic component 400. In accordance with some embodiments, the cover layer 104 may cover the plurality of electronic components 400 and the electrical connection structure 10E. In accordance with some embodiments, the cover layer 104 may cover the first test pad 191, the second test pad 192, the plurality of electronic components 400 and the electrical connection structure 10E, but it is not limited thereto. The cover layer 104 can provide at least one of the functions of electrical insulation, protection of the related components that are covered, flat surface, etc. The cover layer 104 may be formed by coating, spraying, dispensing, printing or another suitable method, but it is not limited thereto. In accordance with some embodiments, the cover layer 104 may include an inorganic material, an organic material, or a combination thereof, but it is not limited thereto. In accordance with some embodiments, the inorganic material may include silicon nitride, silicon oxide, silicon oxynitride, aluminum oxide, another suitable material, or a combination thereof, but it is not limited thereto. In accordance with some embodiments, the organic material may include, for example, perfluoroalkoxy alkane (PFA), polytetrafluoroethylene (PTFE), perfluorinated ethylene propylene (FEP), polyethylene, silicone, acrylic, polyurethane epoxy, another suitable material or a combination thereof, but it is not limited thereto.

In accordance with some embodiments, the second substrate 200 is disposed below the first substrate 100, and the second substrate 200 and the plurality of electronic components 400 are located on opposite surfaces of the first substrate 100. The second substrate 200 can serve as a circuit substrate. In accordance with some embodiments, the second substrate 200 may include a printed circuit board (PCB), a redistribution layer (RDL), or a combination thereof, but it is not limited thereto. In accordance with some other embodiments, the second substrate 200 may include a chip on film (COF), but it is not limited thereto.

Specifically, in accordance with some embodiments, the second substrate 200 may include a base and multiple insulating layers and interconnect layers (e.g., patterned conductive layers) disposed on the base. As shown in FIG. 2, in accordance with some embodiments, the electronic device 10 may further include an insulating layer 202 and a second conductive pad 210. The insulating layer 202 and the second conductive pad 210 may also be part of the insulating layer and interconnect layer of the second substrate 200. The insulating layer 202 and the second conductive pad 210 may be disposed between the second substrate 200 and the first substrate 100. In accordance with some other embodiments, the second substrate 200 may be an interposer.

The base of the second substrate 200 may include a rigid substrate, a flexible substrate, or a combination thereof. In accordance with some embodiments, the material of the base of the second substrate 200 may include glass, quartz, sapphire, polyimide (PI), polycarbonate (PC), polyethylene terephthalate (PET), polypropylene (PP), polydimethylsiloxane (PDMS), another suitable base material or a combination thereof, but it is not limited thereto.

In accordance with some embodiments, the insulating layer 202 may include a polymer insulating material, for example, may include Ajinomoto Build-up Film (ABF), polybenzoxazole (PBO), polyimide (PI), photosensitive polyimide (PSPI), benzocyclobutene (BCB), PrePreg, photoimageable dielectric (PID), resin coated cooper foil (RCC), flame-resistant fiberglass (FR4), fiberglass resin composite material, another suitable insulating material or a combination thereof, but it is not limited thereto.

In accordance with some embodiments, the electronic device 10 may further include an intermediate layer 102, and the intermediate layer 102 may be disposed between the first substrate 100 and the second substrate 200. In detail, a part of the intermediate layer 102 may be disposed between the insulating layer 202 and the first substrate 100, and a part of the intermediate layer 102 may be disposed between the second substrate 200 and the first substrate 100. In accordance with some embodiments, the intermediate layer 102 may be an adhesive layer that can combine the first substrate 100 and the second substrate 200. For example, the intermediate layer 102 may be disposed on the second substrate 200 and then be combined with the first substrate 100, or the intermediate layer 102 may be disposed on the first substrate 100 and then combined with the second substrate 200. In accordance with some embodiments, the material of the intermediate layer 102 may include an inorganic material, an organic material, or a combination thereof, but it is not limited thereto. In accordance with some embodiments, the inorganic material may include silicon nitride, silicon oxide, silicon oxynitride, aluminum oxide, another suitable material, or a combination thereof, but it is not limited thereto. In accordance with some embodiments, the organic material may include, for example, perfluoroalkoxy alkane (PFA), polytetrafluoroethylene (PTFE), perfluorinated ethylene propylene (FEP), polyethylene, another suitable material or a combination thereof, but it is not limited thereto. In addition, in accordance with some embodiments, the intermediate layer 102 may include an adhesive material, such as optical clear adhesive (OCA), optical clear resin (OCR), pressure sensitive adhesive (OCR), or optical clear resin (OCR), pressure sensitive adhesive (PSA), acrylic glue, acrylic resin, another suitable material, or a combination thereof, but it is not limited thereto. Furthermore, the intermediate layer 102 may have a single-layer or multi-layer structure.

In addition, the electronic device 10 includes at least one electrical connection structure 10E. The electrical connection structure 10E may be disposed between the electronic components 400, for example, between two adjacent pixels PX1 and PX2, but it is not limited thereto. In other words, in accordance with some embodiments, the electrical connection structure 10E may be disposed in the active area and/or peripheral area of the electronic device 10. The electrical connection structure 10E can be applied to any suitable electronic device to provide electrical connection functions. The detailed structure of the electrical connection structure 10E will be described below.

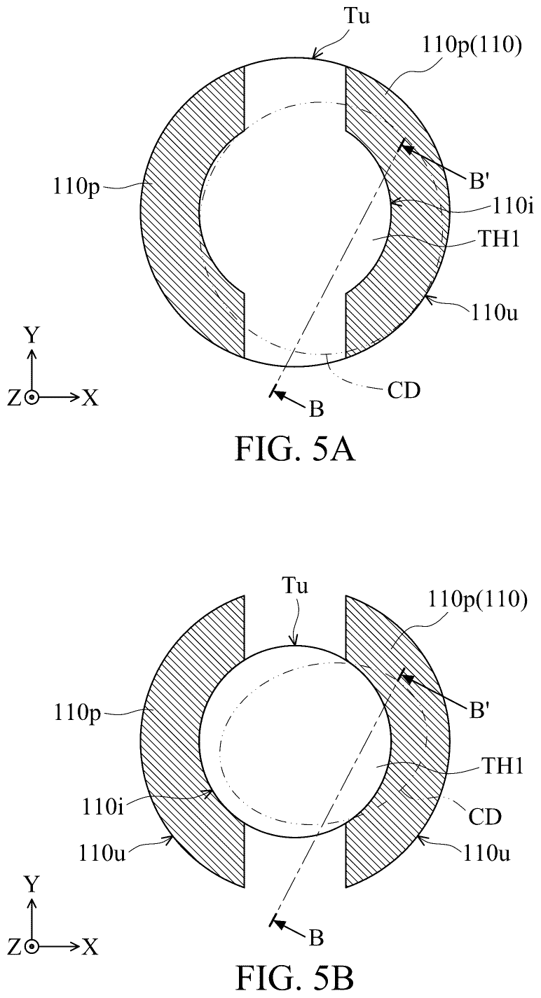

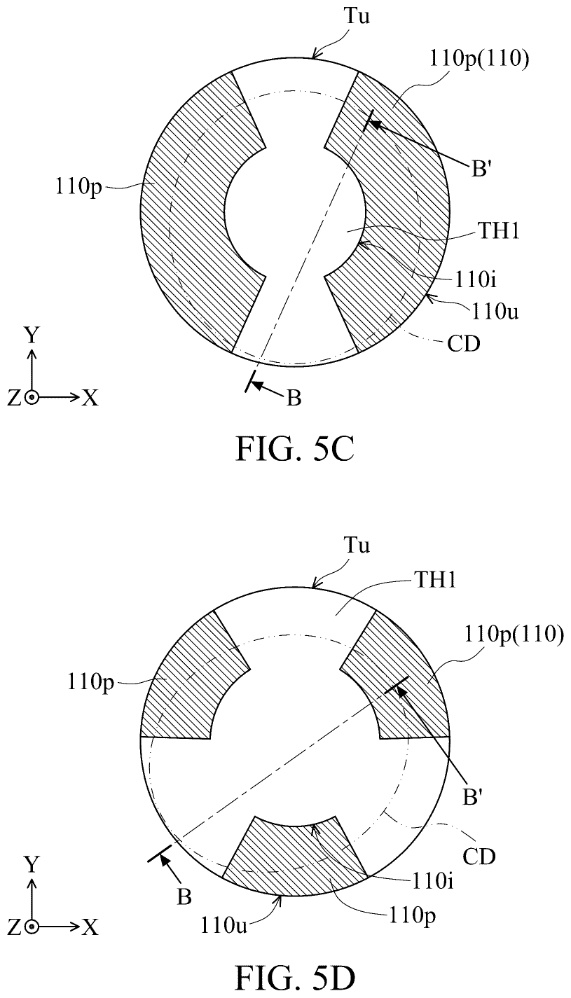

Please refer to FIG. 3 and FIG. 4. FIG. 3 is a cross-sectional diagram of an electrical connection structure 10E of an electronic device in accordance with some embodiments of the present disclosure. FIG. 4 is a top-view diagram of some components of the electrical connection structure 10E of an electronic device in accordance with some embodiments of the present disclosure. Specifically, FIG. 3 is a cross-sectional diagram of the electrical connection structure 10E taken along the section line B-B′ in FIG. 4. Furthermore, FIG. 4 only illustrates the first conductive pad 110, the through hole TH1 and the conductive material CD of the electrical connection structure 10E to clearly explain the positional relationship between them. Moreover, the top-view diagram shown in FIG. 4 substantially corresponds to a horizontal position of the lower surface 110b of the first conductive pad 110 in FIG. 3.

In addition, it should be understood that the components or elements that are the same or similar to those mentioned above will be represented by the same or similar numbers below, and their materials and functions are the same or similar as those mentioned above, and thus will not be repeated in the following description.

First, as shown in FIG. 3, the electrical connection structure 10E may include a first substrate 100, a first conductive pad 110, a second substrate 200, a second conductive pad 210, a through hole TH1 and a conductive material CD.

The first conductive pad 110 may be disposed on the first substrate 100. The first conductive pad 110 includes at least two sub-parts 110p, and the at least two sub-parts 110p each have a first upper surface, a side surface 110s and a lower surface 110b. In accordance with some embodiments, the first conductive pad 110 may be disposed on the topmost insulating layer of the circuit element layer (not illustrated) of the first substrate 100. For example, the lower surface 110b of the sub-part 110p of the first conductive pad 110 may be in contact with the topmost insulating layer of the circuit element layer, but it is not limited thereto.

The first conductive pad 110 may include conductive material. In accordance with some embodiments, the first conductive pad 110 may include a metal conductive material, such as molybdenum (Mo), titanium (Ti), tantalum (Ta), niobium (Nb), hafnium (Hf), nickel (Ni), chromium (Cr), cobalt (Co), zirconium (Zr), tungsten (W), aluminum (Al), copper (Cu), silver (Ag), gold (Au), alloys of the foregoing materials, another suitable conductive material or a combination thereof, but it is not limited thereto. In accordance with some embodiments, the material of the first conductive pad 110 may include a transparent conductive material. The transparent conductive material may include, for example, transparent conductive oxide (TCO), but it is not limited thereto.

The second conductive pad 210 may be disposed on the second substrate 200. The second conductive pad 210 includes an upper surface 210t. In accordance with some embodiments, the second conductive pad 210 may be a part of the interconnect layer of the second substrate 200, but it is not limited thereto. In accordance with some embodiments, the second conductive pad 210 may be further electrically connected to an electronic component (not illustrated, which may be, for example, a driving component) disposed on the second substrate 200.

Furthermore, the material of the second conductive pad 210 may be the same or similar to the material of the first conductive pad 110, and thus will not be repeated here.

In accordance with some embodiments, the electrical connection structure 10E may further include an intermediate layer 102, which may be disposed between the first substrate 100 and the second substrate 200 and partially cover the second conductive pad 210.

The through hole TH1 may pass through the first substrate 100. In accordance with some embodiments, the through hole TH1 may pass through the first substrate 100 and the intermediate layer 102 and expose a portion of the upper surface 210t of the second conductive pad 210. As shown in FIG. 4, in a top-view diagram, the conductive material CD is partially disposed in the through hole TH1 and is in contact with at least one first upper surface 110t of the sub-part 110p of the first conductive pad 110 and the upper surface 210t of the second conductive pad 210. The first conductive pad 110 may be electrically connected to the second conductive pad 210 through the through hole TH1. The conductive material CD may pass through the through hole TH1, so that the first conductive pad 110 and the second conductive pad 210 may be electrically connected to each other. In accordance with some embodiments, the first conductive pad 110 may be electrically connected to the second conductive pad 210 through at least one of the two sub-parts 110p. In accordance with some embodiments, the conductive material CD may be in contact with the upper surface 110t, the side surface 110s of the sub-part 110p of the first conductive pad 110, and the upper surface 210t of the second conductive pad 210. In accordance with some embodiments, the conductive material CD may be in contact with the upper surface 110t, the side surfaces 110s of the sub-part 110p of the first conductive pad 110, the first substrate 100, the intermediate layer 102, and the upper surface 210t of the second conductive pad 210.

As shown in FIG. 3, in accordance with some embodiments, the side surface THs of the through hole TH1 may be substantially perpendicular to the upper surface 210t of the second conductive pad 210. In accordance with some other embodiments, the side surface THs of the through hole TH1 may not be perpendicular to the upper surface 210t of the second conductive pad 210. That is, the side surface THs of the through hole TH1 may be inclined, for example, may be inclined inward (the top width of the through hole TH1 smaller than the bottom width), or may be inclined outward (the top width of the through hole TH1 is larger than the bottom width). In accordance with some other embodiments, the side surface THs of the through hole TH1 may have irregular profile, but it is not limited thereto.

Furthermore, the conductive material CD may be partially filled in the through hole TH1 or entirely filled in the through hole TH1. For example, in accordance with some other embodiments (not illustrated), during the process of filling the through hole TH1 with the conductive material CD, there may be a gap between the side surface of the conductive material CD in the through hole TH1 and the side surface THs of the through hole TH1. In accordance with some embodiments (not illustrated), a portion of the side surface of the conductive material CD may not in contact with the side surface THs of the through hole TH1 and/or the side surface 102s of the intermediate layer 102. During the process of disposing the conductive material CD in the through hole TH1, the air bubbles generated can be released through the gap between the side surface of the conductive material CD and the side surface THs of the through hole TH1. In this way, the risk of bubbles existing in the conductive material CD can be reduced, thereby reducing the problem of poor contact or abnormal electrical connection between the conductive material CD and the first conductive pad 110 or the second conductive pad 210.

In accordance with some embodiments, part of the first substrate 100 and the intermediate layer 102 may be removed through one or more photolithography processes and/or etching processes to form the through hole TH1. In accordance with some embodiments, the photolithography process may include photoresist coating (e.g., spin coating), soft baking, hard baking, mask alignment, exposure, post-exposure baking, photoresist development, cleaning and drying, etc., but it is not limited thereto. The etching process may include a dry etching process or a wet etching process, but it is not limited thereto.

Furthermore, the conductive material CD may include a conductive material. In accordance with some embodiments, the conductive material CD may include silver paste, copper paste, conductive solder, another suitable conductive material, or a combination thereof, but it is not limited thereto. In accordance with some embodiments, the conductive material CD may be disposed in the through hole TH1 by using solder paste printing, micro inkjet printing (MJP) process, chemical vapor deposition (CVD) process, physical vapor deposition (PVD) process, an electroplating process, an electroless plating process, another suitable method or a combination thereof.

As described above, the first conductive pad 110 includes at least two sub-parts 110p. In accordance with some embodiments, as shown in FIG. 4, the at least two sub-parts 110p are separated from each other, and the sub-parts 110p may be disposed at the periphery of the through hole TH1. In other words, the sub-parts 110p of the first conductive pad 110 may not entirely surround the through hole TH1. In accordance with some embodiments, the two sub-parts 110p may be disposed oppositely, or symmetrically disposed on both sides of the geometric center (not illustrated) of the through hole TH1, but it is not limited thereto. In accordance with some embodiments, in the normal direction of the first substrate 100 (for example, the Z direction in the figure), the inner edge 110i of the sub-part 110p of the first conductive pad 110 does not overlap with the geometric center of the through hole TH1.

It should be noted that the first conductive pad 110 is usually made of a metal material with greater hardness, if the sub-part 110p is disposed in the area corresponding to the center of the through hole TH1, it may be detrimental to the drilling process of forming the through hole. Therefore, arranging the sub-part 110 of the first conductive pad 110 at the periphery of the through hole TH1 can improve the yield of the drilling process.

In accordance with some embodiments, in a top-view diagram or in the normal direction of the first substrate 100 (for example, the Z direction in the figure), the conductive material CD may at least partially overlap with at least one of the sub-parts 110p of the first conductive pad 110. In accordance with some embodiments, the outer edge Tu of the through hole TH1 may be at least partially aligned with the outer edge 110u of at least one of the sub-parts 110p. In the design aspect, it is hoped that the outer edge Tu of the through hole TH1 can be aligned with the outer edge 110u of at least one of the sub-parts 110p. However, in the manufacturing process, such as the process of manufacturing the through hole TH1 and/or the first conductive pad 110, there may be a process tolerance between the design value and the actual value. In accordance with some embodiments, in a top-view diagram, the outer edge Tu of the through hole TH1 and the outer edge 110u of at least one of the sub-parts 110p are at least partially overlapped or slightly misaligned (not illustrated). In accordance with some embodiments, the curvature of the outer edge 110u of the sub-part 110p of the first conductive pad 110 may be substantially the same as the curvature of the inner edge 110i.

Furthermore, the sub-parts 110p may have the same or different shapes. In accordance with some embodiments, the sub-part 110p of the first conductive pad 110 may have an arc-shaped, curved or concave profile, but it is not limited thereto. Specifically, in accordance with some embodiments, the inner edge 110i and/or the outer edge 110u of the sub-part 110p may have an arc-shaped, curved or concave profile. In accordance with some embodiments, in a top-view diagram, the sub-part 110p of the first conductive pad 110 may have a rounded corner (not illustrated). For example, the rounded corners may be disposed at one, two, three or four corners of the sub-part 110p, but it is not limited thereto. Furthermore, the through hole TH1 may have a circular-like main part and two sector-shaped parts connected to the main part.

In addition, it should be understood that the amount of sub-parts 110p of the first conductive pad 110 is not limited to two, and the first conductive pad 110 may have any suitable amount of sub-parts 110p, for example, three, four, five six, seven, eight, nine, ten, eleven or twelve, etc., but it is not limited thereto.

It should be noted that, in addition to providing a vertical electrical connection through conduction between the first conductive pad 110 and the second conductive pad 210 through the conductive material CD, the sub-parts 110p of the first conductive pad 110 can also serve as a plurality of terminals for providing lateral electrical connection. The contact points between the conductive material CD and the first conductive pad 110 can be increased, and the difficulty of the wiring process of the electrical connection structure can be reduced. In particular, the plurality of sub-parts 110p of the first conductive pad 110 can also enable the filling process of the conductive material CD and/or the drilling process of the through hole TH1 to have a larger error tolerance, thereby improving the process yield. In addition, through the configuration of the plurality of sub-parts 110p of the first conductive pad 110, the total area of the first conductive pad 110 can be relatively reduced, the volume of the through holes TH1 and/or the conductive material can be maintained or increased, and the reliability of the electrical connection structure can be improved.

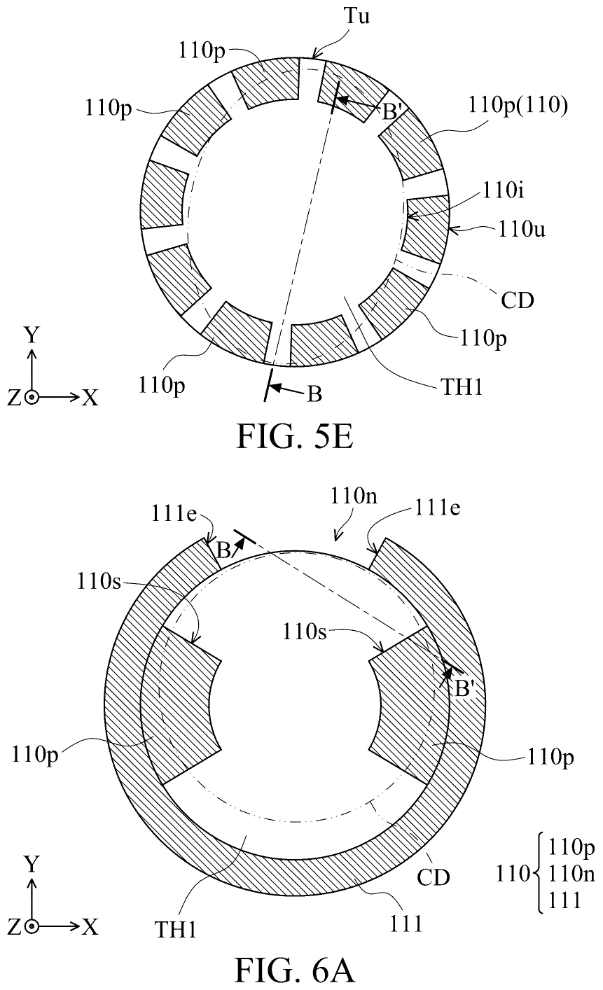

Next, please refer to FIGS. 5A to 5E, which are top-view diagrams of some components of an electrical connection structure of an electronic device in accordance with some other embodiments of the present disclosure. Similarly, FIGS. 5A to 5E only illustrate the first conductive pad 110, the through hole TH1 and the conductive material CD of the electrical connection structure to clearly explain the positional relationship between them. Moreover, the top-view diagrams shown in FIGS. 5A to 5E substantially correspond to a horizontal position of the lower surface 110b of the first conductive pad 110 in FIG. 3.

Please refer to FIG. 5A. In this embodiment, the first conductive pad 110 has two sub-parts 110p. The two sub-parts 110p are separated from each other. The sub-parts 110p may be disposed at the periphery of the through hole TH1. Furthermore, in the normal direction of the first substrate 100 (for example, the Z direction in the figure), the inner edge 110i of the sub-part 110p of the first conductive pad 110 does not overlap with the geometric center of the through hole TH1, and the conductive material CD at least partially overlaps with the sub-part 110p of the first conductive pad 110. In this embodiment, the outer edge Tu of the through hole TH1 may be at least partially aligned with the outer edge 110u of the sub-part 110p. In the design aspect, it is hoped that the outer edge Tu of the through hole TH1 can be aligned with the outer edge 110u of at least one of the sub-parts 110p. However, during the manufacturing process, such as the process of manufacturing the through hole TH1 and/or the first conductive pad 110, there may be a process tolerance between the design value and the actual value. In accordance with some embodiments, in a top-view diagram, the outer edge Tu of the through hole TH1 and the outer edge 110u of at least one of the sub-parts 110p are at least partially overlapped or slightly misaligned (not illustrated). In addition, the curvature of the outer edge 110u of the sub-part 110p of the first conductive pad 110 may be substantially the same as the curvature of the inner edge 110i, and the inner edge 110i and/or the outer edge 110u of the sub-part 110p of the first conductive pad 110 may have ab arc-shaped, curved or concave profile. In this embodiment, the through hole TH1 may have a circular-like main part and two rectangular-like parts connected to the main part.

Please refer to FIG. 5B. In this embodiment, the first conductive pad 110 has two sub-parts 110p. The two sub-parts 110p are separated from each other. The sub-parts 110p may be disposed at the periphery of the through hole TH1. Furthermore, in the normal direction of the first substrate 100 (for example, the Z direction in the figure), the inner edge 110i of the sub-part 110p of the first conductive pad 110 does not overlap with the geometric center of the through hole TH1, and the conductive material CD at least partially overlaps with the sub-part 110p of the first conductive pad 110. In this embodiment, the outer edge Tu of the through hole TH1 may be at least partially aligned with the inner edge 110i of the sub-part 110p. In the design aspect, it is hoped that the outer edge Tu of the through hole TH1 can be aligned with the inner edge 110i of at least one of the sub-parts 110p. However, in the manufacturing process, such as the process of manufacturing the through hole TH1 and/or the first conductive pad 110, there may be a process tolerance between the design value and the actual value. In accordance with some embodiments, in a top-view diagram, the outer edge Tu of the through hole TH1 and the inner edge 110i of at least one of the sub-parts 110p are at least partially overlapped or slightly misaligned (not illustrated). In other words, the outer edge Tu of the through hole TH1 may shrink inward compared to the outer edge 110u of the sub-part 110p. In addition, the curvature of the outer edge 110u of the sub-part 110p of the first conductive pad 110 may be substantially the same as the curvature of the inner edge 110i, and the inner edge 110i and/or the outer edge 110u of the sub-part 110p of the first conductive pad 110 may have an arc-shaped, curved or concave profile. In this embodiment, the through hole TH1 may have a circular-like shape.

Please refer to FIG. 5C. In this embodiment, the first conductive pad 110 has two sub-parts 110p. The two sub-parts 110p are separated from each other. The sub-parts 110p may be disposed at the periphery of the through hole TH1. Furthermore, in the normal direction of the first substrate 100 (for example, the Z direction in the figure), the inner edge 110i of the sub-part 110p of the first conductive pad 110 does not overlap with the geometric center of the through hole TH1, and the conductive material CD at least partially overlaps with the sub-part 110p of the first conductive pad 110. In this embodiment, the outer edge Tu of the through hole TH1 may be at least partially aligned with the outer edge 110u of the sub-part 110p. In the design aspect, it is hoped that the outer edge Tu of the through hole TH1 can be aligned with the outer edge 110u of at least one of the sub-parts 110p. However, during the manufacturing process, such as the process of manufacturing the through hole TH1 and/or the first conductive pad 110, there may be a process tolerance between the design value and the actual value. In accordance with some embodiments, in a top-view diagram, the outer edge Tu of the through hole TH1 and the outer edge 110u of at least one of the sub-parts 110p are at least partially overlapped or slightly misaligned (not illustrated). In addition, the curvature of the outer edge 110u of the sub-part 110p of the first conductive pad 110 may be substantially the same as the curvature of the inner edge 110i, and the inner edge 110i and/or the outer edge 110u of the sub-part 110p of the first conductive pad 110 may have an arc-shaped, curved or concave profile. In this embodiment, the through hole TH1 may have a circular-like main part and two sector-shaped parts connected to the main part.

Please refer to FIG. 5D. In this embodiment, the first conductive pad 110 has three sub-parts 110p. The three sub-parts 110p are separated from one another. The sub-parts 110p may be disposed at the periphery of the through hole TH1. Furthermore, in the normal direction of the first substrate 100 (for example, the Z direction in the figure), the inner edge 110i of the sub-part 110p of the first conductive pad 110 does not overlap with the geometric center of the through hole TH1, and the conductive material CD at least partially overlaps with the sub-part 110p of the first conductive pad 110. In this embodiment, the outer edge Tu of the through hole TH1 may be at least partially aligned with the outer edge 110u of the sub-part 110p. In the design aspect, it is hoped that the outer edge Tu of the through hole TH1 can be aligned with the outer edge 110u of at least one of the sub-parts 110p. However, during the manufacturing process, such as the process of manufacturing the through hole TH1 and/or the first conductive pad 110, there may be a process tolerance between the design value and the actual value. In accordance with some embodiments, in a top-view diagram, the outer edge Tu of the through hole TH1 and the outer edge 110u of at least one of the sub-parts 110p are at least partially overlapped or slightly misaligned (not illustrated). In addition, the curvature of the outer edge 110u of the sub-part 110p of the first conductive pad 110 may be substantially the same as the curvature of the inner edge 110i, and the inner edge 110i and/or the outer edge 110u of the sub-part 110p of the first conductive pad 110 may have an arc-shaped, curved or concave profile. In this embodiment, the through hole TH1 may have a circular-like main part and three sector-shaped parts connected to the main part.

Please refer to FIG. 5E. In this embodiment, the first conductive pad 110 has ten sub-parts 110p. The ten sub-parts 110p are separated from one another. The sub-parts 110p may be disposed at the periphery of the through hole TH1. Furthermore, in the normal direction of the first substrate 100 (for example, the Z direction in the figure), the inner edge 110i of the sub-part 110p of the first conductive pad 110 does not overlap with the geometric center of the through hole TH1, and the conductive material CD at least partially overlaps with the sub-part 110p of the first conductive pad 110. In this embodiment, the outer edge Tu of the through hole TH1 may be at least partially aligned with the outer edge 110u of the sub-part 110p. In the design aspect, it is hoped that the outer edge Tu of the through hole TH1 can be aligned with the outer edge 110u of at least one of the sub-parts 110p. However, during the manufacturing process, such as the process of manufacturing the through hole TH1 and/or the first conductive pad 110, there may be a process tolerance between the design value and the actual value. In accordance with some embodiments, in a top-view diagram, the outer edge Tu of the through hole TH1 and the outer edge 110u of at least one of the sub-parts 110p are at least partially overlapped or slightly misaligned (not illustrated). In addition, the curvature of the outer edge 110u of the sub-part 110p of the first conductive pad 110 may be substantially the same as the curvature of the inner edge 110i, and the inner edge 110i and/or the outer edge 110u of the sub-part 110p of the first conductive pad 110 may have an arc-shaped, curved or concave profile. In this embodiment, the through hole TH1 may have a circular-like main part and ten sector-shaped parts connected to the main part.

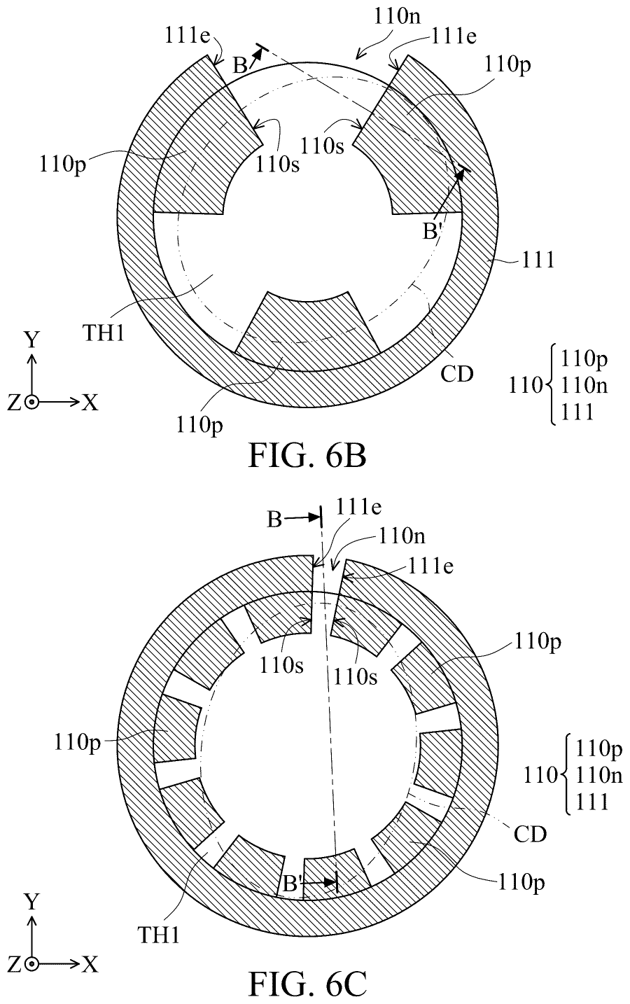

Next, please refer to FIGS. 6A to 6C, which are top-view diagrams of some components of an electrical connection structure of an electronic device in accordance with some other embodiments of the present disclosure. Similarly, FIGS. 6A to 6C only illustrate the first conductive pad 110, the through hole TH1 and the conductive material CD of the electrical connection structure to clearly explain the positional relationship between them. Moreover, the top-view diagrams shown in FIGS. 6A to 6C substantially correspond to a horizontal position of the lower surface 110b of the first conductive pad 110 in FIG. 3.

As shown in FIGS. 6A to 6C, in accordance with some embodiments, the first conductive pad 110 may further include a connection part 111, and the connection part 111 is connected to at least two sub-parts 110p. In accordance with some embodiments, the connection part 111 may be electrically connected to the sub-part 110p. In accordance with some embodiments, the connection part 111 may contact at least two sub-parts 110p and connect the at least two sub-parts 110p together in series. The connection part 111 may be disposed at the periphery of the sub-part 110p. Furthermore, in accordance with some embodiments, the connection part 111 may at least partially surround the through hole TH1, and the connection part 111 may merely partially surround the through hole TH1 without entirely surrounding the through hole TH1. In other words, the first conductive pad 110 may further include a notch portion 110n adjacent to the connection part 111, and the connection part 111 may partially surround the through hole, and the notch portion 110n may be located between the end portions 111e of the connection part 111. The notch portion 110n can discharge air bubbles generated during the manufacturing process.

In accordance with some embodiments, in a top-view diagram, the shape of the connection part 111 may be a ring shape with a notch. In addition, it should be understood that although the connection part 111 in the drawings only has one notch portion 110n, according to different embodiments, the connection part 111 may have other suitable numbers and/or other suitable sizes of the notch portions 110n. Furthermore, in accordance with some embodiments, in the normal direction of the first substrate 100 (for example, the Z direction in the figure), in addition to overlapping the sub-part 110p of the first conductive pad 110, the conductive material CD may also partially overlap with the connection part 111.

Please refer to FIG. 6A. In this embodiment, the first conductive pad 110 has two sub-parts 110p, and the two sub-parts 110p are connected to the connection part 111. In this embodiment, the end portion 111e of the connection part 111 is not aligned with the side surface 110s of the sub-part 110p. The end portion 111e of the connection part 111 protrudes from the side surface 110s of the sub-part 110p. In other words, the end portion 111e of the connection part 111 may have an overhang structure.

Please refer to FIG. 6B. In this embodiment, the first conductive pad 110 has three sub-parts 110p, and the three sub-parts 110p are connected to the connection part 111. In this embodiment, the end portions 111e of the connection part 111 are substantially aligned with the side surfaces 110s of the two sub-parts 110p.

Please refer to FIG. 6C. In this embodiment, the first conductive pad 110 has ten sub-parts 110p, and the ten sub-parts 110p are connected to the connection part 111. In this embodiment, the end portions 111e of the connection part 111 are substantially aligned with the side surfaces 110s of the two sub-parts 110p.

It should be noted that the impedance of the first conductive pad 110 can be further reduced with the configuration of the connection part 111. When the conductive material CD is in contact with the sub-parts 110p and/or the connection part 111 of the first conductive pad 110, the contact resistance between the sub-parts 110p and/or the connection part 111 and the conductive material can be reduced.

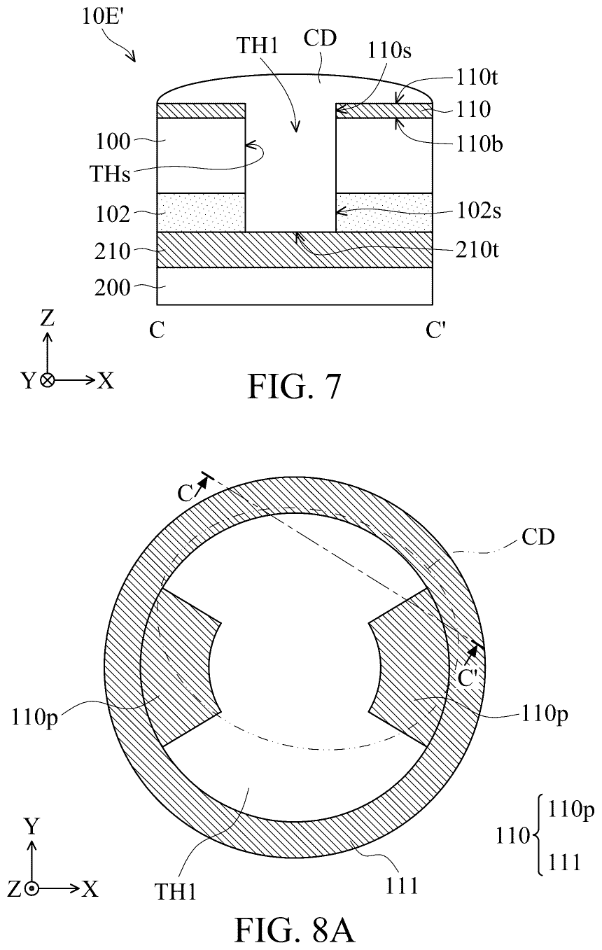

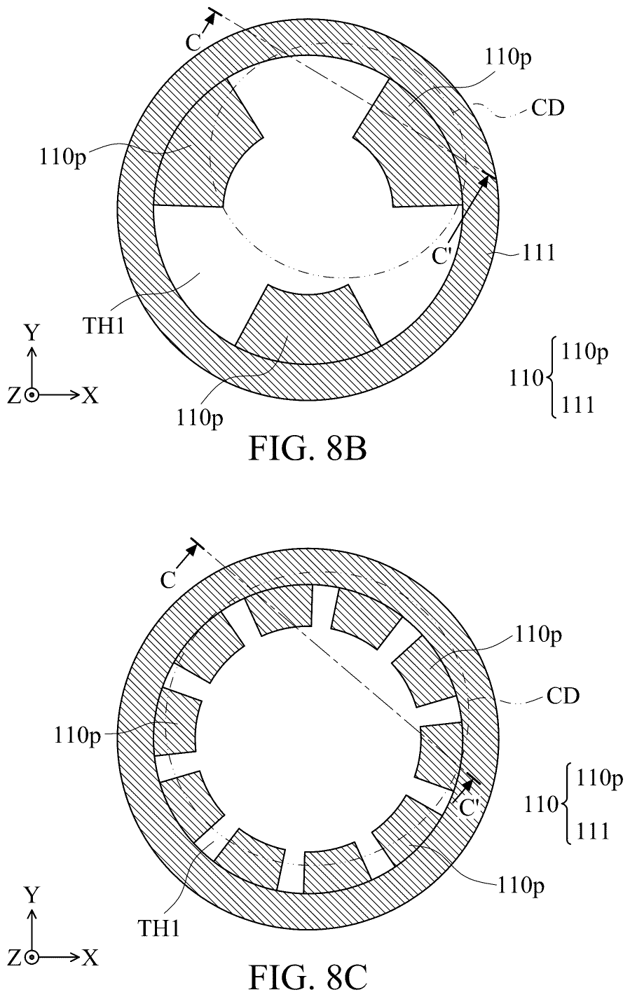

Please refer to FIG. 7 and FIGS. 8A to 8C. FIG. 7 is a cross-sectional diagram of the electrical connection structure 10E of an electronic device in accordance with some other embodiments of the present disclosure. FIGS. 8A to 8C are top-view diagrams of some components of the electrical connection structure 10E of an electronic device in accordance with some other embodiments of the present disclosure. Specifically, FIG. 7 is a cross-sectional diagram of the electrical connection structure 10E taken along the cross-section line C-C′ of FIGS. 8A to 8C. Furthermore, FIGS. 8A to 8C only illustrate the first conductive pad 110, the through hole TH1 and the conductive material CD of the electrical connection structure 10E to clearly explain the positional relationship between them. Moreover, the top-view diagrams shown in FIGS. 8A to 8C substantially correspond to the horizontal position of the lower surface 110b of the first conductive pad 110 in FIG. 7.

As shown in FIGS. 8A to 8C, in accordance with some embodiments, the first conductive pad 110 may further include the connection part 111, and the connection part 111 is connected to at least two sub-parts 110p. The connection part 111 may contact at least two sub-parts 110p and connect the at least two sub-parts 110p together in series. The connection part 111 may be disposed at the periphery of the sub-part 110p. Furthermore, in accordance with some embodiments, the connection part 111 may entirely surround the through hole TH1. In other words, the first conductive pad 110 may not have the notch portion 110n. In a top-view diagram, the shape of the connection part 111 may be annular (ring-shaped). In accordance with some embodiments, the entirety of the first conductive pad 110 (including the sub-parts 110p and the connection part 111) may substantially have a symmetrical structure. Furthermore, in accordance with some embodiments, in the normal direction of the first substrate 100 (for example, the Z direction in the figure), in addition to overlapping the sub-part 110p of the first conductive pad 110, the conductive material CD may also partially overlap with the connection part 111.

Similarly, the arrangement of the ring-shaped connection part 111 can further reduce the impedance of the first conductive pad 110. When the conductive material CD is in contact with the sub-part 110p and/or the connection part 111 of the first conductive pad 110, the contact resistance between the sub-parts 110p and/or connection part 111 and the conductive material.

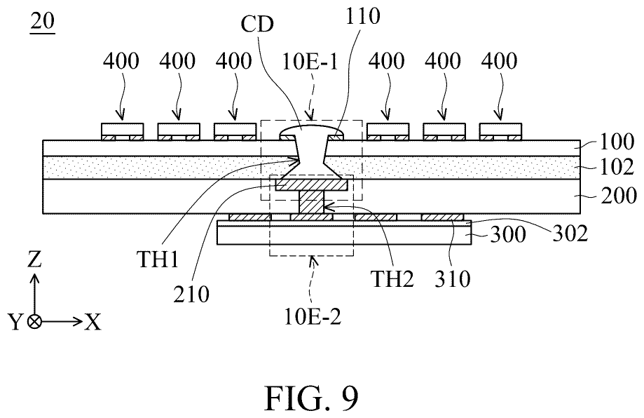

Please refer to FIG. 9, which is a cross-sectional diagram of an electronic device 20 in accordance with some embodiments of the present disclosure. It should be understood that, for clarity of explanation, some components of the electronic device 20 may be omitted in the drawings, and only some components are schematically illustrated. In accordance with some embodiments, additional features may be added to the electronic device 20 described below. In accordance with some other embodiments, some features of the electronic device 20 described below may be replaced or omitted.

As shown in FIG. 9, in accordance with some embodiments, the electronic device 20 includes an electrical connection structure 10E-1 and an electrical connection structure 10E-2. Specifically, the electrical connection structure 10E-1 is substantially the same as the electrical connection structure 10E in the embodiments shown in FIG. 2. Compared with the electronic device 10 shown in FIG. 2, the electronic device 20 further includes the electrical connection structure 10E-2. The electrical connection structure 10E-2 can be electrically connected to the electrical connection structure 10E-1. In accordance with some embodiments, in the normal direction of the first substrate 100 (for example, the Z direction in the figure), the electrical connection structure 10E-2 and the electrical connection structure 10E-1 at least partially overlap.

In detail, in accordance with some embodiments, the electrical connection structure 10E-2 may include a third substrate 300, a third conductive pad 310 and a through hole TH2. The third conductive pad 310 may be disposed between the third substrate 300 and the conductive pad 210, and the through hole TH2 may pass through the second substrate 200, and the third conductive pad 310 may be electrically connected to the second conductive pads 210 through the through hole TH2. Specifically, a conductive material is also disposed in the through hole TH2, and the third conductive pad 310 can be electrically connected to the second conductive pad 210 through the conductive material disposed in the through hole TH2.

The materials of the third substrate 300 and the third conductive pad 310 may be the same or similar to the materials of the aforementioned second substrate 200 and the second conductive pad 210, and thus will not be repeated here.

Furthermore, the electronic device 20 may include an electronic component 400 and a driving component 302. The electronic component 400 may be disposed on the first substrate 100, and the driving component 302 may be disposed on the third substrate 300. Moreover, the driving component 302 may be electrically connected to the electronic component 400 by the electrical connection structure 10E-1 and the electrical connection structure 10E-2. As mentioned above, in accordance with some embodiments, the electronic component 400 may include a light-emitting diode, but it is not limited thereto. Furthermore, in accordance with some embodiments, the driving component 302 may include an integrated circuit chip (IC), a microchip, or another suitable electronic driving component that can provide electronic signals or logic signals, but it is not limited thereto. In accordance with some embodiments, the driving component 302 may be disposed on the third substrate 300 in the form of a chip on film (COF) package or a chip on glass (COG) package, but it is not limited thereto.

The conductive material CD of the electronic device 20 can be electrically connected to the second conductive pad 210 and the third conductive pad 310 through the through holes TH1 and TH2, and then electrically connected to the driving component 302 on the third substrate 300. Through the above configuration, the driving signal of the driving component 302 can be provided to the first conductive pad 110 and multiple electronic components through the conductive path formed by the conductive material CD, the second conductive pad 210 and the third conductive pad 310. When the electronic device 20 is applied in the field of display devices, the driving signal of the driving component 302 can be transmitted from one side of the first substrate 100 to the electronic components 400 on the opposite side through the electrical connection structure 10E-1 and the electrical connection structure 10E-2. Therefore, the driving component 302 can be disposed on the back side of the first substrate 100, thereby reducing the usage rate of the peripheral area of the electronic device 20, thereby achieving technical requirements such as borderless, narrow border or seamless tiling. The electronic device 20 can therefore have good display quality.

In addition, in accordance with some other embodiments, the aforementioned electrical connection structure can also be applied to the tiled device to provide electrical connections between different parts of the tiled device. Moreover, the electrical connection structure can be used to provide conduction between any suitable amount of substrates, and the amount of electrical connection structures and substrates is not limited to those shown in the drawings of the present disclosure.

To summarize the above, in accordance with the embodiments of the present disclosure, the conductive pads of the electrical connection structure provided have a plurality of sub-parts, which can serve as a plurality of terminals for the conductive pads to be electrically connected laterally. In this way, the contact points between the conductive material and the conductive pad can be increased, the difficulty of wiring process of the electrical connection structure can be reduced. This also allows the conductive material filling process and/or drilling process to have a larger error tolerance, thus improving the process yield. In addition, through the configuration of the aforementioned conductive pads, the total area of the conductive pads can be relatively reduced, and the volume of the through hole and/or the conductive material can be maintained or increased, which can make the electrical connection structure have improved reliability and beneficial to realize the miniaturization of the electrical connection structure.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
at least one electrical connection structure, wherein the at least one electrical connection structure comprises:
a first substrate;
a first conductive pad disposed on the first substrate, wherein the first conductive pad comprises at least two sub-parts, and the at least two sub-parts respectively comprise a first upper surface;
a second substrate;
a second conductive pad disposed on the second substrate, wherein the second conductive pad comprises a second upper surface;
a through hole that passes through the first substrate and exposes a portion of the second upper surface; and
a conductive material partially disposed in the through hole and in contact with at least one first upper surface and the second upper surface.

2. The electronic device as claimed in claim 1, wherein the at least two sub-parts are separated from each other.

3. The electronic device as claimed in claim 1, wherein the first conductive pad further comprises a connection part connected to the at least two sub-parts.

4. The electronic device as claimed in claim 3, wherein the connection part is in contact with the at least two sub-parts and connects the at least two sub-parts together in series.

5. The electronic device as claimed in claim 1, wherein the first conductive pad comprises a connection part, and the connection part at least partially surrounds the through hole.

6. The electronic device as claimed in claim 5, wherein the first conductive pad further comprises a notch portion, the notch portion is adjacent to the connection part, and the connection part partially surrounds the through hole.

7. The electronic device as claimed in claim 5, wherein the connection part entirely surrounds the through hole.

8. The electronic device as claimed in claim 1, further comprising:
an intermediate layer disposed between the first substrate and the second substrate and partially covering the second conductive pad, wherein the through hole passes through the first substrate and the intermediate layer and exposes a portion of the second upper surface.

9. The electronic device as claimed in claim 1, wherein the first conductive pad is electrically connected to the second conductive pad through at least one of the at least two sub-parts.

10. The electronic device as claimed in claim 1, wherein an outer edge of the through hole is at least partially aligned with an outer edge of at least one of the at least two sub-parts.

11. The electronic device as claimed in claim 1, wherein an outer edge of the through hole is at least partially aligned with an inner edge of at least one of the at least two sub-parts.

12. The electronic device as claimed in claim 1, wherein the at least two sub-parts are disposed at the periphery of the through hole.

13. The electronic device as claimed in claim 1, wherein an inner edge of at least one of the at least two sub-parts does not overlap with a geometric center of the through hole.

14. The electronic device as claimed in claim 1, wherein in a top-view diagram, an inner edge and/or an outer edge of at least one of the at least two sub-parts has an arc-shaped, curved or concave profile.

15. The electronic device as claimed in claim 1, wherein in a top-view diagram, at least one of the at least two sub-parts has a rounded corner.

16. The electronic device as claimed in claim 1, further comprising another electrical connection structure, wherein the another electrical connection structure is electrically connected to the at least one electrical connection structure.

17. The electronic device as claimed in claim 16, wherein the another electrical connection structure at least partially overlaps the at least one electrical connection structure.

18. The electronic device as claimed in claim 16, wherein the another electrical connection structure comprises:
a third substrate; and
a third conductive pad disposed between the third substrate and the second conductive pad.

19. The electronic device as claimed in claim 18, wherein the another electrical connection structure further comprises:
another through hole passing through the second substrate, wherein the third conductive pad is electrically connected to the second conductive pad through the another through hole.

20. The electronic device as claimed in claim 18, further comprising:
an electronic component disposed on the first substrate; and
a driving element disposed on the third substrate,
wherein the driving element is electrically connected to the electronic component through the at least one electrical connection structure and the another electrical connection structure.
